(19) United States
(12) Patent Application Publication
(10) Pub. No.: US 2016/0100486 A1
(43) Pub. Date: Apr. 7, 2016

(54) Display Module with Curved Surface

(71) Applicant: AU OPTRONICS CORPORATION, Hsin-Chu (TW)

(72) Inventors: YING-JI CHEN, Hsin-Chu (TW); MEI-CHUN CHENG, Hsin-Chu (TW); TENG-LIANG YU, Hsin-Chu (TW); CHE-HAO YANG, Hsin-Chu (TW); CHIA-CHU WANG, Hsin-Chu (TW)

(21) Appl. No.: 14/860,026

(22) Filed: Sep. 21, 2015

(30) Foreign Application Priority Data
Oct. 3, 2014 (TW) 103134592

(51) Int. Cl. H05K 1/18; H05K 1/02; G06F 3/041

(52) U.S. Cl. CPC H05K 1/189; G06F 3/041; H05K 1/0296; G06F 2203/04102; H05K 2201/10128; H05K 2201/09227

(57) ABSTRACT

A display module is provided including a display panel and an integrated circuit unit. The display panel is curved into a curved shape around a curvature axis and has a curved side, wherein the side also curves around the curvature axis. The integrated circuit unit is formed as a long stripe shape and has a first long side extending along an extending direction of the integrated circuit unit. The integrated circuit unit is directly or indirectly connected to the side, and the first long side extends along the extending direction of the curvature axis. Since the extending direction of the integrated circuit unit is aligned with the curvature axis, the integrated circuit unit will not be easily affected by the curvature of the display panel.

### BACKGROUND

1. Technical Field

The present disclosure generally relates to a curved surface display module; particularly, the present disclosure relates to a curved surface display module having upright integrated circuit unit.

2. Description of the Related Art

In recent years, flat panel display devices have been widely used in various fields. To satisfy consumer preferences and increasing demands as well as to provide better visual experiences, display devices with curved surfaces have begun to surface on the market. When manufacturing curved surface display devices, in addition to using flexible display panels, other accompanying components would correspondingly need to be adjusted to work seamlessly with the display panel.

FIG. 1A illustrates a conventional curved surface display device. As shown in FIG. 1A, the curved surface display device includes a curved display panel 10, a flexible circuit board 30, and an integrated driver circuit 50. The integrated driver circuit 50 is disposed on the flexible circuit board 30, and the flexible circuit board 30 is electrically connected to the signal lines on the curved display panel 10 to transmit output signals of the integrated driver circuit 50 to the curved display panel 10. As shown in FIG. 1A, the integrated driver circuit 50 has a long side 51, and the long side 51 is parallel to a side 11 where the flexible circuit board 30 connects to the curved display panel 10.

When assembling, the flexible circuit board 30 is typically bent backwards to the backside of the curved display panel 10. If the integrated driver circuit 50 is disposed in a position on the flexible circuit board 30 relatively further away from the curved display panel 10, the integrated driver circuit 50 would be folded back to the backside of the curved display panel 10. However, under these conditions, since the backside of the curved display panel 10 is also a curved surface, the integrated driver circuit 50 will not be able to adhere smoothly onto the backside of the curved display panel 10. In another scenario, as shown in FIG. 1B, the integrated driver circuit 50 may also be folded to the bottom end of the curved display panel 10. However, with regards to the above mentioned installation positions, the integrated driver circuit 50 is susceptible to breakage or damage from external impact or during transport.

### SUMMARY

It is an object of the present disclosure to provide a display module to increase flexibility in terms of modular design and assembly.

It is another object of the present disclosure to provide a display module to decrease chances of damage to integrated circuit units.

It is yet another object of the present disclosure to provide a display module to decrease the circumstance of the integrated circuit units interfering with the curved display panel.

The display module includes a display panel and an integrated circuit unit, wherein the display panel is curved around a center axis of a virtual curvature. The display panel has a curved side, and the curved side curves around the center axis to form a curvature. The integrated circuit unit is formed as a bar shape, and has a first long side extending along the extending direction of the integrated circuit unit. The integrated circuit unit is directly or indirectly connected to the side, and the first long side extends along the direction of extension of the axis of curvature. Through this design, since the elongated direction of the integrated circuit unit is the same as the direction of the axis of the curvature of the display panel, the dependability of the circuits and positioning of the integrated circuit are not easily affected by the curvature levels of the display panel. Additionally, the rigidity of the integrated circuit unit itself will not increase the difficulties when the display panel is being curved.

### BRIEF DESCRIPTION OF THE DRAWINGS

FIGS. 1A and 1B show a conventional curved display device;

FIG. 2 is an embodiment of the display module;

FIG. 3 is another embodiment of the display module;

FIG. 4 is an embodiment of the flexible circuit board being folded back to the backside of the display panel;

FIG. 5 is a cross-sectional view of the integrated circuit unit being accommodated in the recess on the back board;

FIG. 6 is an embodiment of the integrated circuit unit and the flexible circuit board;

FIG. 7 is another embodiment of the integrated circuit unit and the flexible circuit board;

FIG. 8 is another embodiment of the integrated circuit unit and the flexible circuit board;

FIG. 9 is another embodiment of the integrated circuit unit and the flexible circuit board; and

FIG. 10 is another embodiment of the display module.

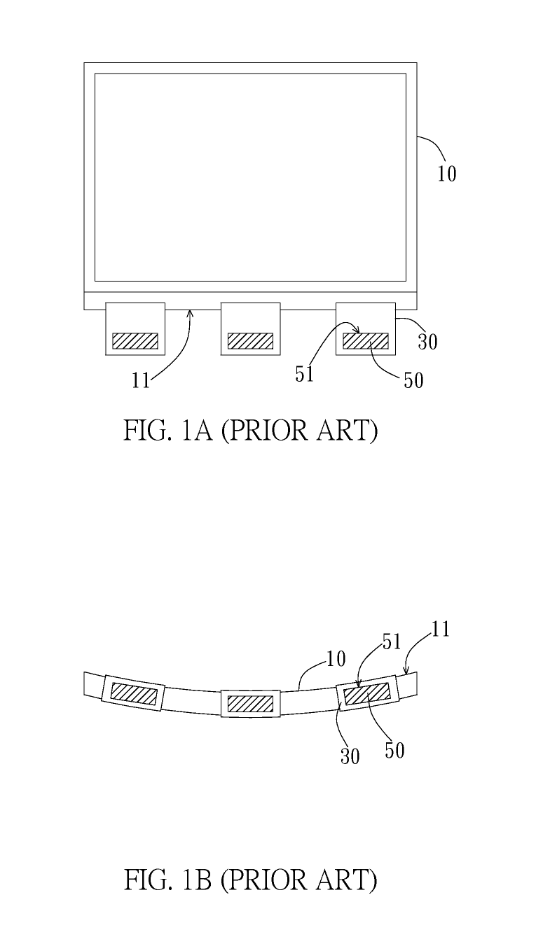

### DETAILED DESCRIPTION OF THE PREFERRED EMBODIMENT

The present disclosure provides a display module. In an embodiment, the display module utilizes a liquid crystal display panel with a backlight module to generate images. However, in other different embodiments, the display module can also utilize other types of display panels. For instance, organic light-emitting diode display panels, electrophoretic display panels, or other self-luminance or non self-luminance panels may be used.

As illustrated in FIG. 2, the display module includes a display panel 100 and an integrated circuit unit 300. As described previously, the display panel 100 may be different types of self-luminous or non self-luminous display panels and is curved in a curved shape. In an embodiment, a display surface 101 and a back surface 103 of the display panel 100 are correspondingly curved such that at different positions the same spacing is between the display surface 101 and the back surface 103. However, in other different embodiments, the display surface 101 and the back surface 103 may have different levels of curvatures such that at different positions of the display panel 100, the thickness is different. As shown in FIG. 2, the display panel 100 is preferably curved into a curved shape around a virtual curvature axis 200. In an embodiment, the curvature axis 200 is the curvature center of the display panel 101. The display panel 100 has a curved side 110, wherein the side 110 preferably also curves into a curved shape around the curvature axis 200.

The integrated circuit unit 300 preferably includes signal driver circuit, gate driver circuit, or other circuit components. No limitation is implied. As illustrated in FIG. 2, the integrated circuit unit 300 is formed as a long stripe shape and has a first long side 301 extending along the extending direction of the integrated circuit board 300. The integrated circuit unit 300 is directly or indirectly connected to the side 110, and the first long side 301 extends along an extending direction X of the curvature axis 200. In terms of an embodiment, the extending direction of the first long side 301 is parallel with the axial direction of the curvature produced by the display panel 100, or otherwise the extending direction X of the curvature axis 200. By way of this design, since the extending direction of the integrated circuit unit 300 is the same as the axial direction of the curvature produced by the display panel 100, the position of the integrated circuit unit 300 and the durability of the circuits would not be as easily affected by the curvature levels of the display panel 100. In addition, the rigidity of the integrated circuit unit 300 itself will not increase the difficulty when the display panel 100 is being curved.

As illustrated in the embodiment of FIG. 2, the display module further includes a flexible circuit board 500 connected to the side 110. A plurality of connection pads are above the area of the display panel 100 near to the side 110, and are used to electrically connect with the flexible circuit board 500. The integrated circuit unit 300 is directly disposed on the flexible circuit board 500 to indirectly connect to the side 110. The integrated circuit unit 300 is electrically connected to the circuit paths on the flexible circuit board 500 and is then electrically connected to the display panel 100 through the connection pad (not shown) such that signals may be transmitted. Since the flexible circuit board 500 itself is flexible, the curvature of the display panel 100 will not compromise the circuit board 500 in position or circuit reliability. When the integrated circuit unit 300 is disposed on the flexible circuit board 500, the integrated circuit unit 300 will maintain the characteristic of the direction of extension being perpendicular to the side 110. In this manner, the integrated circuit unit 300 can be prevented from being affected by the curvature of the display panel 100.

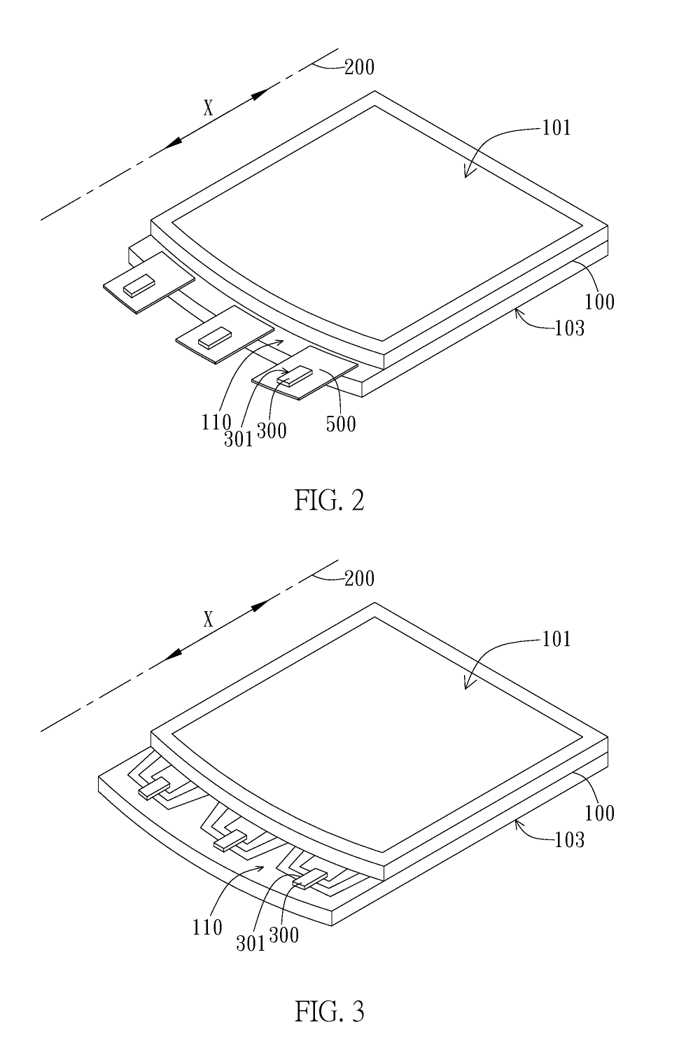

As shown in the embodiment in FIG. 3, the integrated circuit unit 300 is directly disposed in the area of the side 110 of the display panel 100, wherein preferably its position is maintained on the board of the display panel 100. In this design, although the length of the integrated circuit board 300 may cause the side portion of the display panel 100 to increase in thickness, the integrated circuit board 300 will still not be affected by the curvature of the display panel since the length direction of the integrated circuit unit 300 is parallel to the extending direction X of the curvature axis 200.

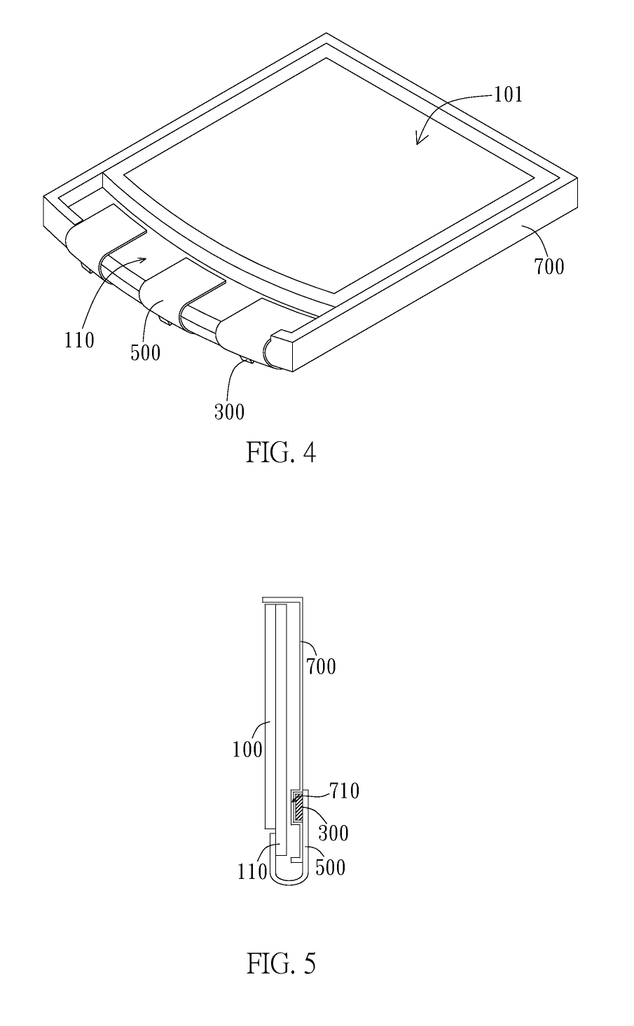

As illustrated in the embodiment of FIG. 4, the display module additionally includes a back bezel 700, wherein the display panel 100 is disposed within the back bezel 700. The back bezel 700 is preferably assembled with the display panel 100 from the backside of the display panel 100, wherein the back bezel 700 may be a back board, back frame, or any type of support for the display panel 100, and may also be designed according to requirements to accommodate backlight modules or any other modules with other capabilities. After the flexible circuit board 500 extends out from the side 110, the flexible circuit board 500 further extends outside of the back bezel 700, wherein the portion extending out of the back bezel 700 is folded back to the back bezel 700 corresponding to the backside of the display panel 100. The integrated circuit unit 300 is preferably disposed at the portion where the flexible circuit board 500 folds back to the backside of the back bezel 700, wherein after folding back the first long side 301 preferably maintains extending along the extending direction X of the curvature axis 200. In addition, in a preferred embodiment, for convenience of bending, the length of the side of the flexible circuit board 500 being bent is preferably greater than the length of the side connected to the display panel 100. By way of this design, flexibility in the assembling of the display module can be increased while still maintaining the merit of the integrated circuit unit 300 and the curvature of the display panel 100 not interfering with each other.

FIG. 5 illustrates another embodiment of the display module. In the present embodiment, a recess 710 is formed on the backside of the back bezel 700. The recess 710 is preferably formed from an indentation on the back bezel 700 and having a bottom groove. However, in other different embodiments, the recess 710 may be simply a through hole formed from a puncturing fashion on the backside of the back bezel 700. The recess 710 is provided for accommodating the integrated circuit unit 300, and as such is also preferably formed as a long strip shape to match the shape of the integrated circuit unit 300. The integrated circuit unit 300 is preferably disposed on a surface on the flexible circuit board 500 connecting with the display panel 100. In this manner, when the flexible circuit board 500 is folded back, the integrated circuit unit 300 will extend into the recess 710. Since the integrated circuit unit 300 itself has a thickness and will protrude out past the surface of the flexible circuit board 500, the folded back portion of the flexible circuit board 500 is flatly affixed to the backside of the back bezel 700 when the integrated circuit unit 300 is accommodated in the recess 710. Through this design, the thickness of the display module after assembly may be further reduced. In addition, when the integrated circuit unit 300 is accommodated in the recess 710, the integrated circuit unit 300 can be protected better and will not be as easily susceptible to damage from impacts.

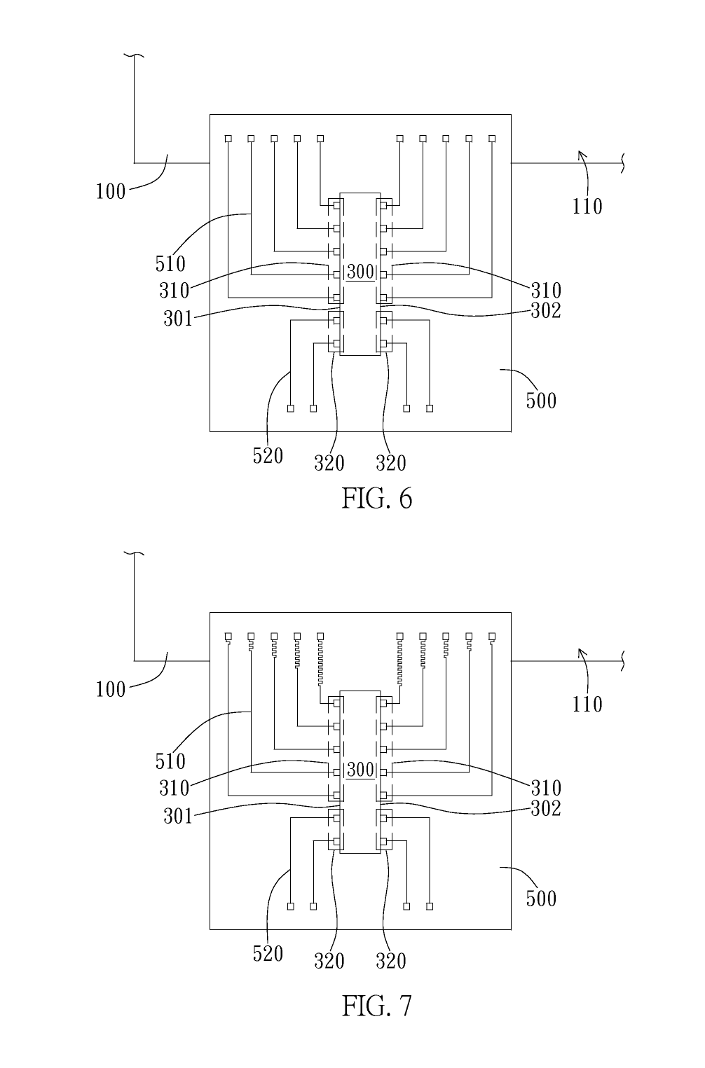

FIG. 6 illustrates an embodiment with the integrated circuit unit 300 disposed on the flexible circuit board 500. As shown in FIG. 6, a plurality of output pins 310 and a plurality of input pins 320 are distributed on the first long side 301. In the present embodiment, the output pins 310 disposed on the first long side 301 at a position closer to the display panel 100 relative to the input pins 320. As shown in FIG. 6, if viewed along the first long side 301, the plurality of output pins 310 are ordered at an end closer to the display panel 100, whereas the plurality of input pins 320 then follow. The input pins 320 preferably receive control signals from systems, such as motherboards or processors and the like, wherein the control signals are processed by the integrated circuit unit 300 into image signals and outputted through the output pins 310 to the display panel 100. In the present embodiment, the quantity of the output pins 310 is greater than the quantity of the input pins 320. As such, the length along the first long side 301 where the output pins 310 are distributed is preferably greater than the length of distribution of the input pins 320 along the first long side 301.

In addition, as shown in FIG. 6, the integrated circuit unit 300 has a second long side 302 acting as the opposing side to the first long side 301. In other words, the second long side 302 is a parallel side along the extending direction of the integrated circuit unit 300. Preferably, there are also output pins 310 and input pins 320 distributed on the second long side 302, wherein the position of the output pins 310 on the second long side 302 is closer to the display panel 100 relative to the input pins 320. In addition, the output pins 310 and the input pins 320 on the first long side 301 and on the second long side 302 are preferably disposed symmetrically. By way of this design of having the output pins 310 closer relatively to the display panel 100, the circuit design on the flexible circuit board 500 may be simplified and may even reduce the surface area requirements of the flexible circuit board 500.

As shown in FIG. 6, a plurality of output lines 510 and a plurality of input lines 520 are included on the flexible circuit board 500. The output lines 510 are positioned outside of the first long side 301 or second long side 302, and respectively are electrically connected to the output pins 310 and extend toward the display panel 100 from the output pins 310. As shown in FIG. 6, the extending direction of the output lines 510 is preferably exits perpendicular to the output pins 310, and then extends turning towards the display panel 110. The input lines 520 are positioned outside of the first long side 301 or the second long side 302, and respectively are electrically connected to the input pins 320, wherein the input lines 520 extend away from the display panel 100 from the input pins 320. As shown in FIG. 6, the extending direction of the input lines 520 is preferably exiting perpendicular to the input pins 320, and then extends turning away from the display panel 110. In addition, the output lines 510 are preferably positioned between the input lines 520 and the display panel 100 in order to save space on the wiring of the output lines 510. By way of the design of the pins of the integrated circuit unit 520 and the wiring design of the flexible circuit board 500, the surface area required by the flexible circuit board 500 may be conserved.

As shown in the embodiment of FIG. 6, the output lines 510 that are connected to the output pins 310 closer to the display panel 100 have paths that are of shorter length. In order to balance out the lengths between different paths, portions of the output lines 310 (ex. Output pins 310 connected closer to the display panel 100) are disposed at least partially in a zigzag manner. By way of this design, the differences in path lengths of different output lines 510 may be reduced in order to increase the overall signal synchronization.

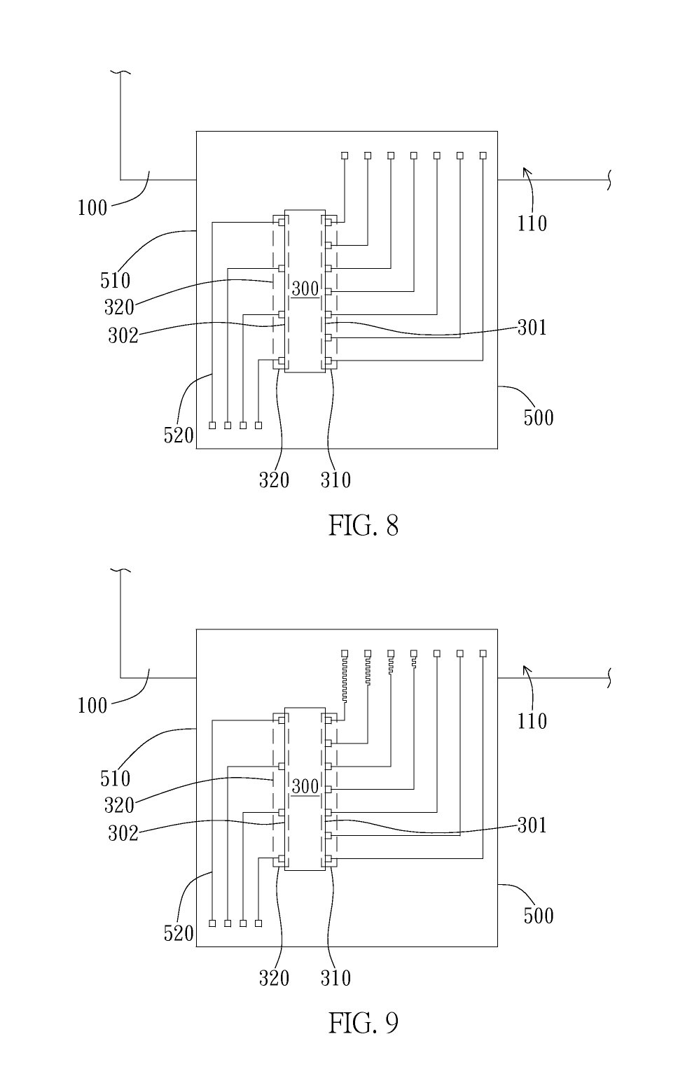

FIG. 8 illustrates another embodiment of the integrated circuit unit 300 and the flexible circuit board 500. As shown in FIG. 8, the output pins 310 and the input pins 320 on the integrated circuit unit 300 are respectively distributed on the first long side 301 and the second long side 302. In other words, the integrated circuit unit 300 of the present embodiment is an integrated circuit unit for conventional horizontal settings. The output lines 510 of the flexible circuit board 500 are positioned outside of the first long side 301 and respectively are electrically connected to the output pins 310, wherein the output lines 510 extend toward the display panel 100 from the output pins 310. As shown in FIG. 8, the extending direction of the output lines 510 is preferably exiting perpendicular to the output pins 310, and then extend turning towards the display panel 110. The input lines 520 are positioned outside of the second long side 302, and are respectively electrically connected to the input pins 320, wherein the input lines 520 then extend away from the display panel 100. As shown in FIG. 8, the extending direction of the input lines 520 is preferably exiting perpendicular to the input pins 320, and then extends turning away from the display panel 110. Since the quantity of the output lines 510 is preferably greater than the quantity of the input lines 520, the integrated circuit unit 300 is preferably disposed biased towards one side of the flexible circuit board 500 such that the side that the output lines 510 are disposed on will have a larger surface area. By way of this design of distributing the output lines 510 and the input lines 520 respectively along the two sides of the integrated circuit unit 300, a better fit may be accomplished with the original integrated circuit unit 300 as there wouldn't be a need to redesign the wiring around the integrated circuit unit 300.

In the embodiment shown in FIG. 8, the output lines 510 connected to the output pins 310 closer to the display panel 100 have relatively shorter path lengths. In order to balance out the path lengths between different lines, as shown in the embodiment of FIG. 9, portions of the output lines 310 (ex. output lines connected to the output pins 310 closer to the display panel 100) may be at least partially disposed in a zigzagging manner. By way of this design, the differences in path lengths between different output lines 510 may be reduced in order to increase the overall signal synchronization.

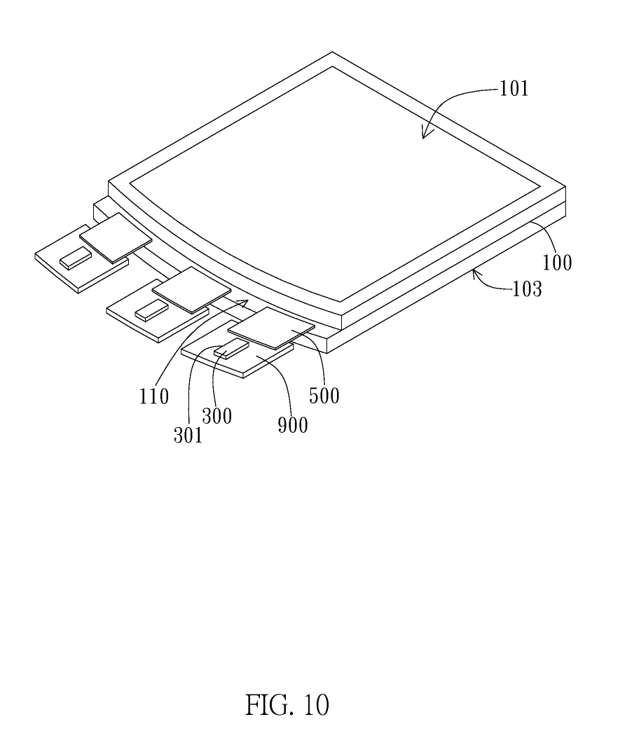

FIG. 10 illustrates another embodiment of the display module. As shown in FIG. 10, the display module further includes a printed circuit board 900 connected to the flexible circuit component on another end opposite to the display panel 100, wherein the printed circuit board 900 in this manner is indirectly connected to the display panel. The integrated circuit unit 300 is directly disposed on the printed circuit board 900 to indirectly be connected to the side 110 through the printed circuit board 900 and the flexible circuit board 500. The integrated circuit unit 300 is electrically connected to the lines on the printed circuit board 900, and is then electrically connected to the lines on the display panel 100 through the flexible circuit board 500 such that signal transmissions may be conducted. When the flexible circuit board 500 needs to be folded back, the entire piece of the printed circuit board 900 may be folded back to the backside of the display panel 100. In addition, in a preferred embodiment, additional lines or more complicated lines may be disposed on the printed circuit board 900 in order to reduce the wiring complexities or surface area requirements thereof on the flexible circuit board 500. In turn, in this manner, design flexibility may be increased.

Although the embodiments of the present disclosure have been described herein, the above description is merely illustrative. Further modification of the invention herein disclosed will occur to those skilled in the respective arts and all such modifications are deemed to be within the scope of the invention as defined by the appended claims.

What is claimed is:

1. A display module, comprising:
a display panel having a side, wherein the display panel is formed with a curvature having at least one curvature axis, the side curves around the curvature axis to form the curvature; and
an integrated circuit unit directly or indirectly connected on the side;
wherein the integrated circuit unit is formed as a stripe shape having a first long side, and the first long side extends along an extending direction of the curvature axis.

2. The display module of claim 1, further comprising a flexible circuit board connected to the side, wherein the integrated circuit unit is disposed on the flexible circuit board to be indirectly connected onto the side.

3. The display module of claim 2, further comprising a back bezel, the display panel is disposed in the back bezel, wherein the flexible circuit board folds from the display panel to a backside of the back bezel corresponding to the display panel.

4. The display module of claim 3, wherein a recess is formed on the backside of the back bezel, and the integrated circuit unit is accommodated within the recess.

5. The display module of claim 2, wherein the integrated circuit unit has a plurality of output pins and a plurality of input pins disposed along the first long side, the output pins are disposed closer to the display panel on the first long side relative to the input pins.

6. The display module of claim 5, wherein the flexible circuit board comprises:
a plurality of output lines positioned outside of the first long side, the output lines are respectively electrically connected to the input pins and extend toward the display panel from the output pins; and
a plurality of input lines positioned outside of the first long side, the input lines are respectively electrically connected to the input pins and extend away to the display panel from the input pins; wherein the output lines are positioned between the input lines and the display panel.

7. The display module of claim 2, wherein the integrated circuit unit has a second long side opposite the first long side, the integrated circuit unit includes: a plurality of output pins disposed along the first long side; and a plurality of input pins disposed along the second long side;
the flexible circuit board includes: a plurality of output lines disposed outside of the first long side and respectively electrically connected to the output pins; and a plurality of input lines disposed outside of the second long side and respectively electrically connected to the input pins.

8. The display module of claim 7, wherein portions of the output lines are disposed zigzagging to decrease differences in path length with other output lines.

9. The display module of claim 1, further comprising:
a flexible circuit board connected to the side; and
a printed circuit board connected to another side of the flexible circuit board opposite to the display panel;
wherein the integrated circuit unit is disposed on the printed circuit board to indirectly connect to the side.

10. A display module, comprising:
a display panel curved in a curved shape, wherein the display panel has a side with a curvature; and
an integrated circuit unit directly or indirectly connected to the side;
wherein the integrated circuit unit is formed as a long stripe shape and has a first long side, the extending direction of the first long side is parallel to an axial direction of the curvature of the display panel.

11. The display module of claim 10, further comprising a flexible circuit board connected to the side; wherein the integrated circuit unit is disposed on the flexible circuit board to indirectly connect to the side.

12. The display module of claim 11, further comprising a back bezel, wherein the display panel is disposed in the back bezel, and the flexible circuit board folds over from the display panel to a backside of the back bezel opposite the display panel.

13. The display module of claim 12, wherein a recess is formed on the backside of the back bezel, and the integrated circuit unit is accommodated in the recess.

14. The display module of claim 13, wherein a plurality of output pins and a plurality of input pins are distributed along the first long side, and the output pins are positioned closer to the display panel along the first long side relative to the input pins.

15. The display module of claim 14, wherein the flexible circuit board includes:
a plurality of output lines positioned outside of the first long side, the output lines respectively electrically connected to the output pins and extend from the output pins toward the display panel; and
a plurality of input lines positioned outside the first long side, the input lines respectively electrically connected to the input pins and extend from the input pins away from the display panel;
wherein the output lines are positioned between the input lines and the display panel.

16. The display module of claim 11, wherein the integrated circuit unit has a second long side corresponding to the first long side, and comprises:
a plurality of output pins distributed along the first long side; and
a plurality of input pins distributed along the second long side;
the flexible circuit board comprises:
a plurality of output lines disposed outside of the first long side and respectively electrically connected to the output pins; and
a plurality of input lines disposed outside the second long side and respectively electrically connected to the input pins.

17. The display module of claim 16, wherein portions of the output lines are disposed zigzagging to decrease differences in path length with other output lines.

18. The display module of claim 10, further comprising:
a flexible circuit board connected to the side; and
a printed circuit board connected to the flexible circuit board at another end opposite the display panel;
wherein the integrated circuit unit is disposed on the printed circuit board to indirectly connect on the side.
